(19) United States
(12) Patent Application Publication
(10) Pub. No.: US 2006/0197144 A1
(43) Pub. Date: Sep. 7, 2006

(54) Nitride storage cells with and without select gate

(76) Inventor: Mammen Thomas, San Jose, CA (US)

Correspondence Address: MAMMEN THOMAS, 1081 CORVETTE DR., SAN JOSE, CA, 95129-2906, US

(21) Appl. No.: 11/068,218

(22) Filed: Mar. 1, 2005

(51) Int. Cl. H01L 29/788

(52) U.S. Cl. 257/316

(57) ABSTRACT

In the past the high voltage needs and cell leakage currents have limited the scalability of the Nitride cell and made the poly silicon floating gate cell the primary contender for Non-Volatile memories. As the process development has matured and technology has scaled to smaller and smaller dimensions, the Poly-silicon floating gate cell has approached its scaling limitations. This has re-kindled the interest in the nitride cell. In order to scale the nitride cell it is necessary to remove the high voltage requirements that limit scaling of the memory junctions and isolation and the high inherent leakage of unselected cells due to over erase of the cells. It is well known that the nitride area where the storage happens is only of the order of 300 Angstroms close to the junctions used for generating the energetic carriers by impact ionization (Channel Hot Electron Programming). The charges once stored do not move around by conduction in Nitride and hence can be considered stationary. Hence it is possible to have Nitride layer covering the areas, where programming happens, to reduce the over all size of the cell while having a control gate between the Nitride storage areas. This type of Nitride storage cell can be implemented with a slight increase in cell size but making the leakage current of non-selected cells a non-issue. A second problem in the prior art is the use of band to band tunneling for erase. This requires high voltages at the drain with negative voltage on gate. The band to band tunneling is a reliability issue for the junction and need a high degree of tuning. A cell using an erase technology and method called the Tunnel Gun (TG) for achieving the erase of the cells is proposed that eliminate this problem. A combination of TG technology with an added select gate will enable the nitride cells to be much more robust and achieve mainstream status in high volume manufacturing.

### FIELD OF INVENTION

This invention relates to the structure and method of Programmable/Erasable Non-Volatile Nitride Memory cell technology for embedded and mass storage applications

### PRIOR ART

Nitride has always held an attraction as a storage element from the early days of Non-Volatile memory due to its capability to accumulate and store charge in the inherent traps that exist in the film. Early efforts at nonvolatile memories using Nitride films are the Metal-Nitride-Oxide Silicon or MNOS structure and the Silicon-Oxide-Nitride-Oxide_Silicon or SONOS structure. The MNOS structure is shown in FIG. 1, and the SONOS structure is shown in FIG. 2. The difference between these structures is how the gate stack is formed over the channel. The MNOS device uses a gate stack comprising a thin Oxide (4), a Nitride storage layer (6), and a Metal layer (9a) directly over the Nitride layer, in that order, all residing over the silicon device channel (3) in a Silicon Substrate, (5) forming a Metal-Nitride-Oxide-Silicon (MNOS) structure between the Source (1) and Drain (2) diffusions of a semiconductor device. The SONOS device uses a gate stack comprising of a thin Oxide layer (4) on Silicon (5) over which is the Nitride storage layer (6), a second Oxide layer (7) on the Nitride layer and a Poly-Silicon layer (9) on top, forming the Poly Silicon-Oxide-Nitride-Oxide-Silicon (SONOS) structure between the source (1) and drain (2) diffusions of a semiconductor device.

Typically these devices have been programmed by enabling the electrons to get in and get trapped in the Nitride by directly applying a high voltage across the dielectric stack between the top conductor and the bottom silicon to produce a voltage gradient across the insulator to cause carriers to move into the Nitride. Similarly the erase was by application of a reverse high voltage sufficient to cause the carriers to move out of the traps into the channel. It has been seen that the needed voltage for this type of operation is substantially large and a complete removal of charge stored in the Nitride is difficult if not impossible by application of high voltages.

Further development of the Nitride based storage has been on hold or on low key due to the development and commercialization of the well known easily manufacturable standard floating gate Non Volatile memory where the charge is allowed to tunnel through and get stored in the floating gate of the memory. The cells in this category include the EEPROMs, the EPROMs and the Flash memory cells of today. These types of memories have been more robust and controllable during program and erase operations and highly reliable in the technology nodes up to 0.18 micron.

As the technologies are being scaled to achieve smaller dimensions and larger densities per unit area, the standard Floating gate Nonvolatile memory is reaching a non scalable region due to the poly silicon stack height and the oxide thickness necessary as well as the voltages needed for program and erase. This in turn has re-kindled an interest in the Nitride storage cell. The standard SONOS Nitride cells have re-emerged with Channel Hot Electron programming and Band-to-Band Tunneling erase or FN tunneling erase as candidates. The problem with the CHE program is that it limits the accumulation of charge to a very small area near the drain of the programming device. As the charge does not spread by conduction in Nitride but remains localized, the read has to ensure that the drain depletion region does not cover the charged area of Nitride during read. Hence a reverse read, reversing the Drain and source, with the programming drain used as source is generally done.

The use of a negative gate voltage on the drain with a high voltage on the source is used to generate hot holes by band-to-band tunneling for erase. These holes that are generated close to the drain depletion is used to erase the charge accumulated during program. The use of these not too well controlled phenomena requires critical drain engineering for program and erases to happen at the same location. This makes the technology of drain engineering very much more complex than a standard MOS device.

May be the most promising prior art development in this regard is the Nitride Mirror bit cell shown in FIG. 3. This is a multi-bit cell, which is capable of storing charge at both ends of the Nitride layer at locations shown (10 and 11) in the Nitride film (6). During programming of bit 1, a high voltage of the order of 5 V is applied to the drain (1) with a high voltage of the order of 11V to the poly gate (9) and ground to the source (1a). This causes a high current flow with impact ionization due to hot electrons at the drain junction. A small portion of the generated CHE will have the velocity component to over come the barrier of Nitride, causing programming by accumulation of negative charge in the traps in the nitride film (6) at storage location (10). Similarly by reversing the source and drain during programming will cause bit 2 to be programmed at location 11. The read of the bit 1 is done by reversing the source and drain used for write, with source (1) and drain (1a) so that the location 11 is covered by the depletion region from the drain voltage while location 10 is in the channel and can modulate the conductance. Similarly bit 2 is read by reversing the drain and source that is with drain (1) and source (1a).

The erase is by applying a high voltage of 8V or higher to the junction to be erased. A negative voltage of close to −2V is applied to the Control gate causing the holes generated by hot carriers due to Band to Band tunneling to be pulled into the Nitride and neutralize the negative charge in the Nitride.

A typical table of voltages for the mirror bit is shown in Table 1.

Some of the problems that exist with the current Nitride cells include:
1. The voltages required on the source and drain of the devices are large for the erase causing cell to cell separation or isolation to be larger than minimum.
2. The high junction voltages also have the problem of increasing the channel lengths of the devices to eliminate punch through and leakage effects.
3. The devices sizes are larger than minimum due to the above two needs.
4. Drain engineering is a complex process for these high voltage junctions where program and erase happen due to different methods using high voltages.
5. Over time the Nitride accumulates charge away from the erase location causing un wanted read characteristics.
6. Cell leakage currents in the unselected cells require that source bias is applied to the array during read operation to increase the Vt of the gate.
7. The high current and high voltages translate to high power dissipation during program and erase.
8. Need for high voltage devices in the data path tend to limit speed.
9. High process complexity and circuit complexity exist due to multiple voltage levels and polarity needs.

The necessity to ensure that the cells do not over erase and unselected cells conduct during read make the circuitry for program erase complex.

What is Proposed is:

Two solutions to the two major problems that limit the use of the Nitride cell of today, that is the cell leakage issue and the high voltage band to band erase.

The cell leakage is the major problem of the Nitride cell as the charge in the Nitride can never be completely removed. This causes minor Vt shifts due to accumulation of positive charge in the device causing the channel to turn on even when the control gate is unselected. Sufficient amount of leakage in the unselected cells can cause false read of data. The current cells try to prevent this by application of a source bias voltage, by applying a voltage to the well. This has the effect of making the Vt of the cell during read higher and making the cell currents smaller and hence slowing down the read operation. A Nitride Select Gate cell is proposed that overcomes this problem of leakage in unselected cells. As is well known the Nitride cell stores charge only at the location where charge penetration and collection in traps take place. This charge does not move around as the material is non conductive. Since the preferred mode of program is the CHE programming the accumulation of charge is limited to the junction depletion region a distance less than 250 A near the junction. Hence it is possible to create Nitride layer of a smaller dimension covering the junction and the depletion region and provide a select region of Poly gate over Oxide such that in the unselected devices the select transistor remains off and prevent unwanted leakage current.

The prior art cells of old used the FN tunneling for erase. This required high voltages and caused over erase problems and unwanted cell leakage in the unselected state. In the current invention the leakage of the cells have been taken care of by the addition of the integrated select gate so it is possible to use the FN tunneling as a means for erase and or program but the issue of scaling and high voltage isolation of the cells will remain a problem. Band to Band tunneling is the most recent mode of erase used with Channel Hot Electron (CHE) programming of the Nitride cells. Band to Band tunneling again needs large voltages to be applied to the junctions and hence cost isolation area. The drain engineering, to have the program by Channel Hot Electrons and erase by Band to Band Tunneling at the same location, is very critical and difficult to achieve. Hence easier alternates like the patented Tunnel Gun Method with lower voltages on gate alone have the advantage when the over erase issues are already taken care of by the select gate.

Some of the Advantages of the Disclosed Structures are:

1. Use of select gate with minimum increase in area of cell to prevent leakage currents from unselected cell impacting the read status of the selected cells.
2. Use of Select gate to reduce the impact of over erase or accumulation of positive charge in the typical case of cells.
3. The use of TG technology for generation of carriers for erase, allowing the reduction of high voltages used for Band to Band tunneling for erase.
4. Improved density and speed due to reduced High Voltage application to the Well and diffusion contacts of the cell.
5. Combined use of TG technology and select gate to reduce the problems faced by the prior art cells and provide a manufacturable cell for High density and embedded NVM applications.

### DESCRIPTION OF DRAWINGS

FIG. 1. Is the cross section of a Prior art Nitride storage cell of MNOS type.

FIG. 2. Is the cross section of a Prior art Nitride storage cell of SONOS type.

FIG. 3. Is the cross section along the channel of a prior art Nitride cell of the Mirror bit type.

FIG. 4. Is the cross section of the cell in FIG. 3 across the channel area.

FIG. 5. Is the cross section along the channel of a Nitride Select Gate (NSG) cell of the present disclosure.

FIG. 6. Is the cross section of the cell in FIG. 5, across the channel at the storage element area.

FIG. 7. Is a Cross section of a Dual Nitride Select Gate (DNSG) cell along the channel.

FIG. 8. Is a cross section of the cell in FIG. 7 across the channel over a storage element area.

FIG. 9. Is a cross section of a Tunnel Gun Nitride (TGN) cell along the channel.

FIG. 10. Is a cross section of cell in FIG. 9 across the channel.

FIG. 11. Is a cross section of a Dual Tunnel Gun Nitride Select Gate (DTGNS) Cell along the channel.

FIG. 12. Is a cross section over a storage element across the channel of the DTGNS cell in FIG. 11.

### EXPLANATION OF NUMBERING AND LETTERING IN THE FIGURES FOR TYPICAL IMPLEMENTATION OF THE TECHNOLOGY

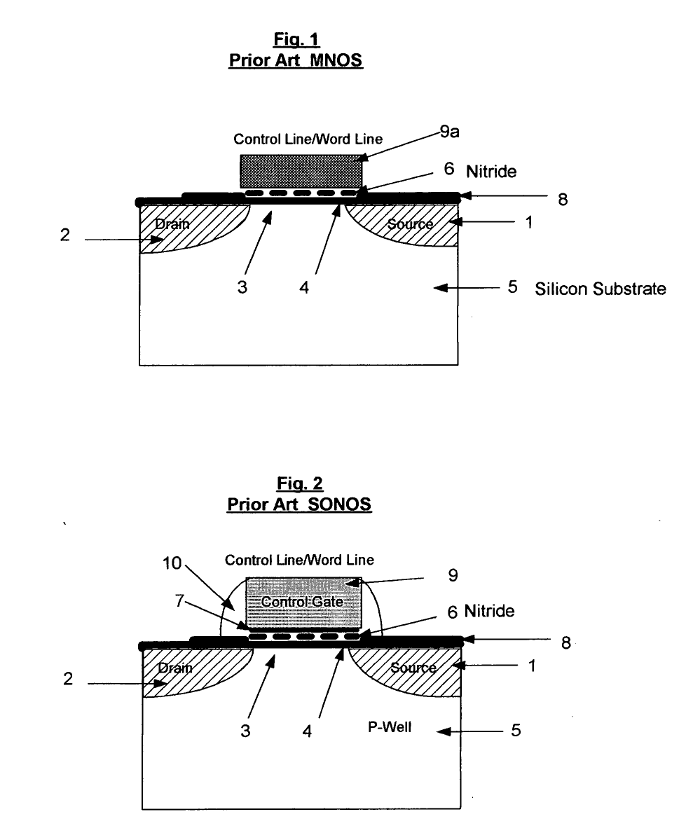

Prior Art NMOS and SONOS Cells FIG. 1, FIG. 2

1. Source Diffusion (S)

2. Drain (D)

3. Channel

4. Oxide

5. Silicon—Well in Substrate

6. Nitride layer

7. Oxide

8. Isolation Oxide

9. Poly Silicon

9a. Metal

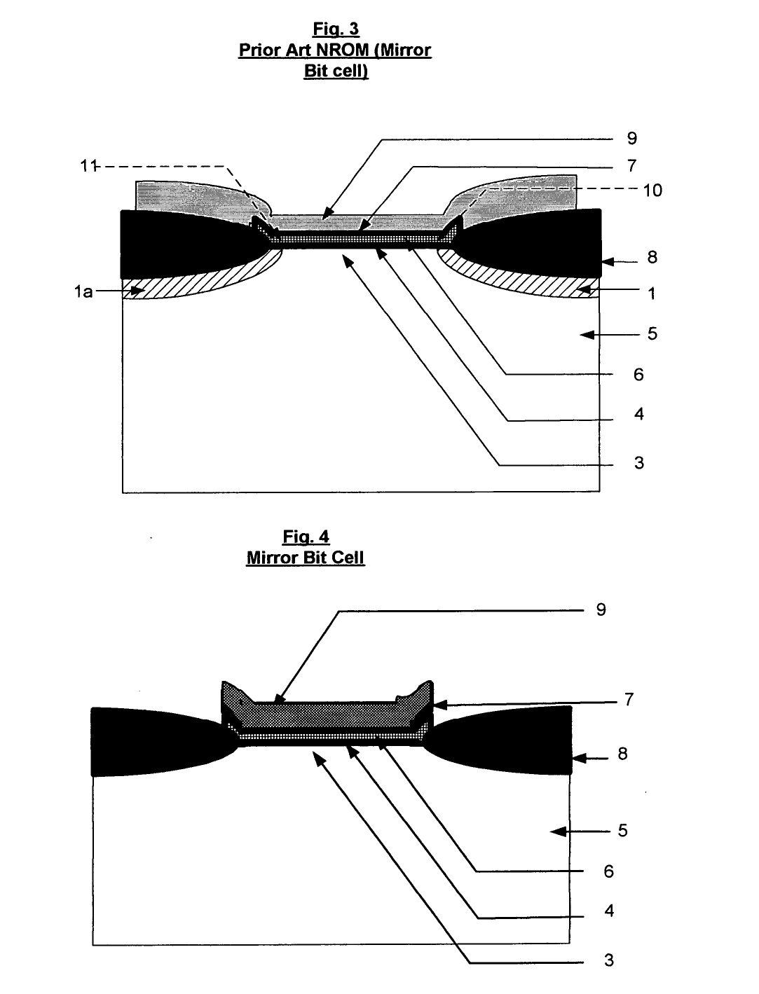

Prior Art Mirror Bit Cell FIG. 3, FIG. 4

1. Diffusion 1 (S/D)

1a. Diffusion 2 (S/D)

3. Channel

4. Oxide (SiO2)

5. Well diffusion in Silicon

6. Nitride layer

7. Oxide

Note: Layer 4,6 and 7 together form an ONO layer where applicable.

8. Isolation

9. Poly Silicon layer Control gate

10. Location of storage of Bit 1

11. Location of Storage of Bit 2

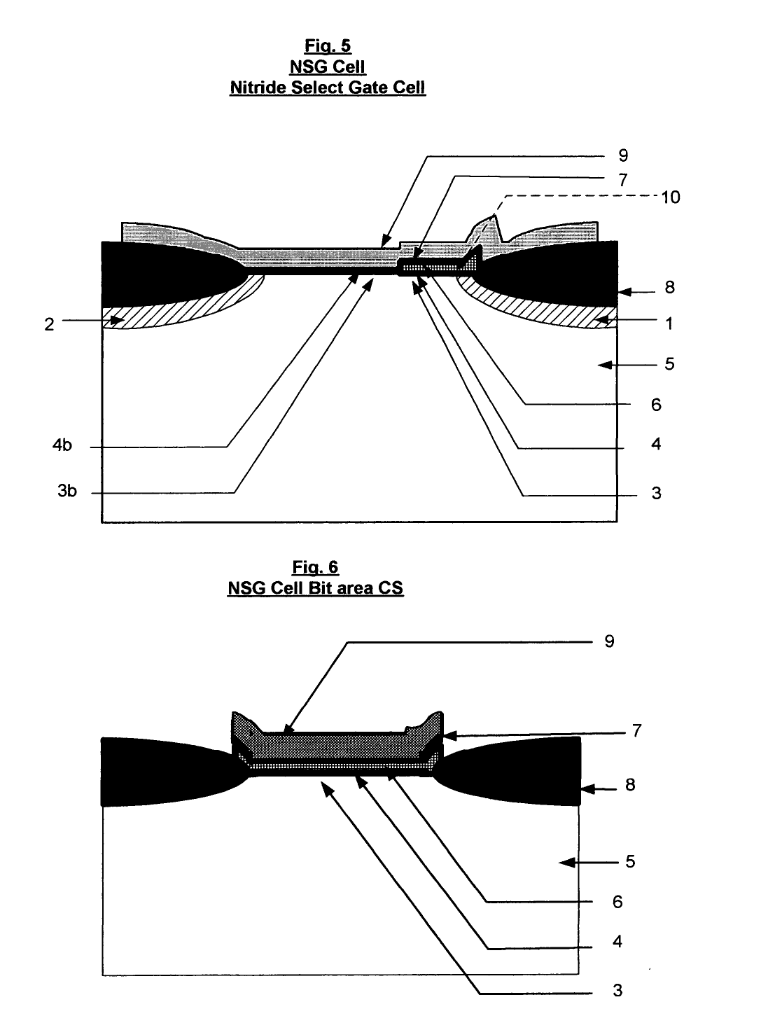

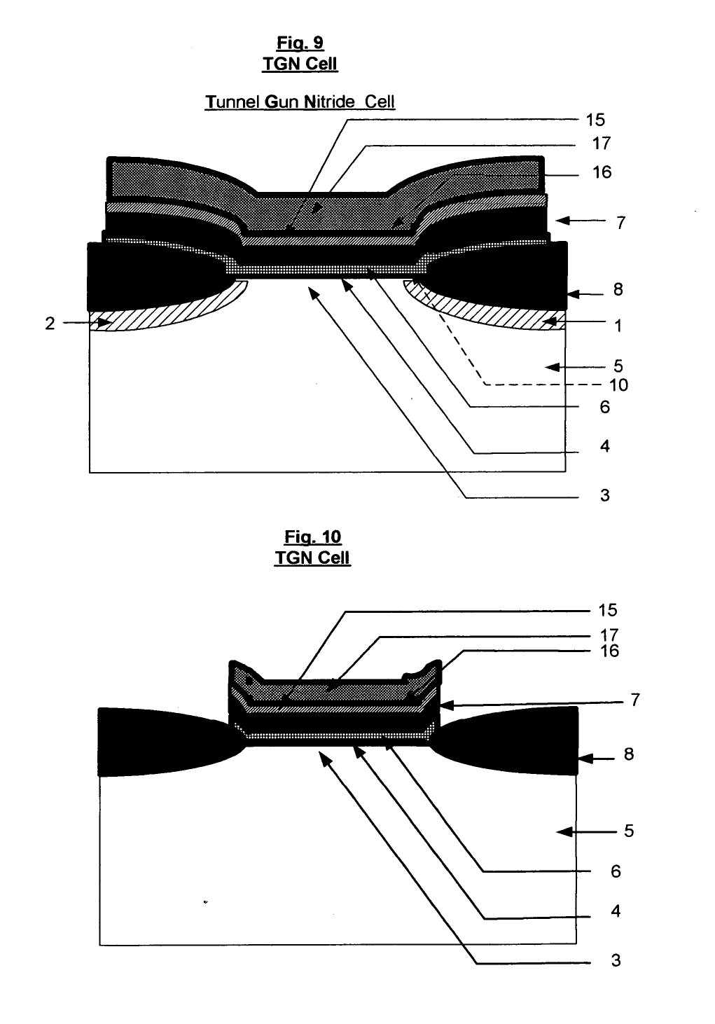

The Disclosed NSG—FIG. 5 and FIG. 6, and TGN—FIG. 9 and FIG. 10

1. Drain diffusion

2. Source Diffusion

3. Channel under the storage element

3b. Channel under the select gate

4. Oxide over the channel adjacent to Diffusion beneath the Nitride layer

4b. Select gate oxide

5. P-well in silicon

6. Nitride layer

7. Oxide layer over the Nitride

Note: layers 4, 6 and 7 form the ONO storage element

8. Isolation Oxide

9. Poly Silicon Control/Select gate

10. bit storage location

15. Collector Grid

16. Barrier Layer

17. Injector layer

Note: Layers 15,16,17 form the Tunnel Gun structure replacing the Polysilicon Control/Select Gate layer (9)

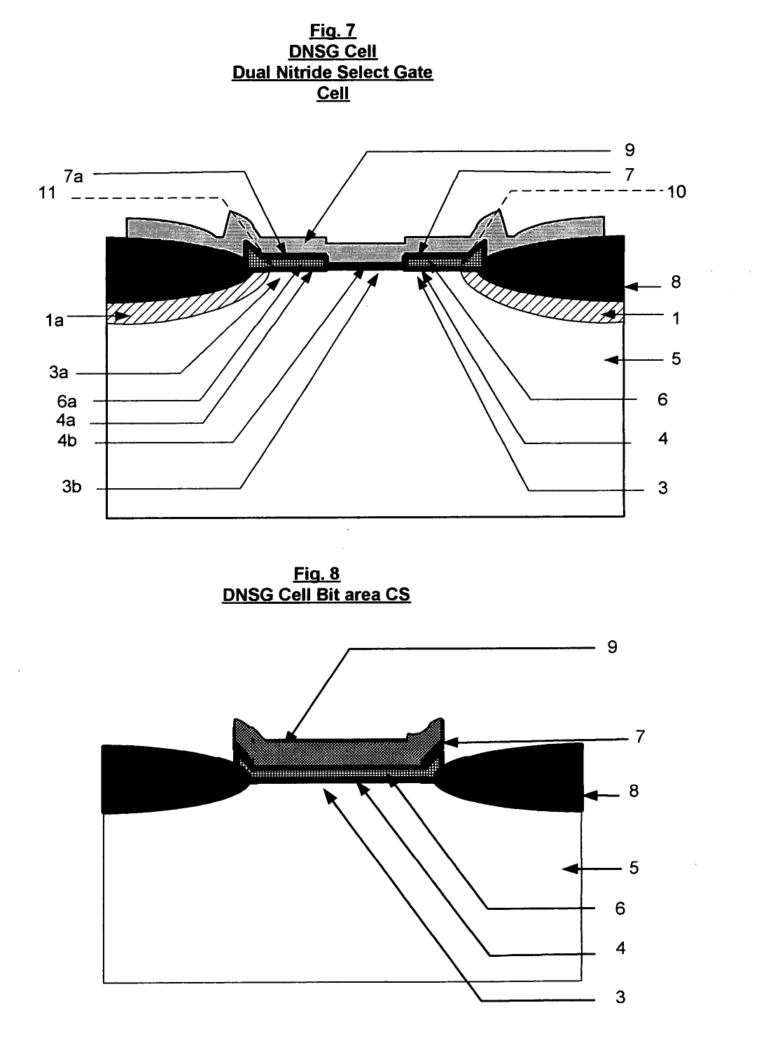

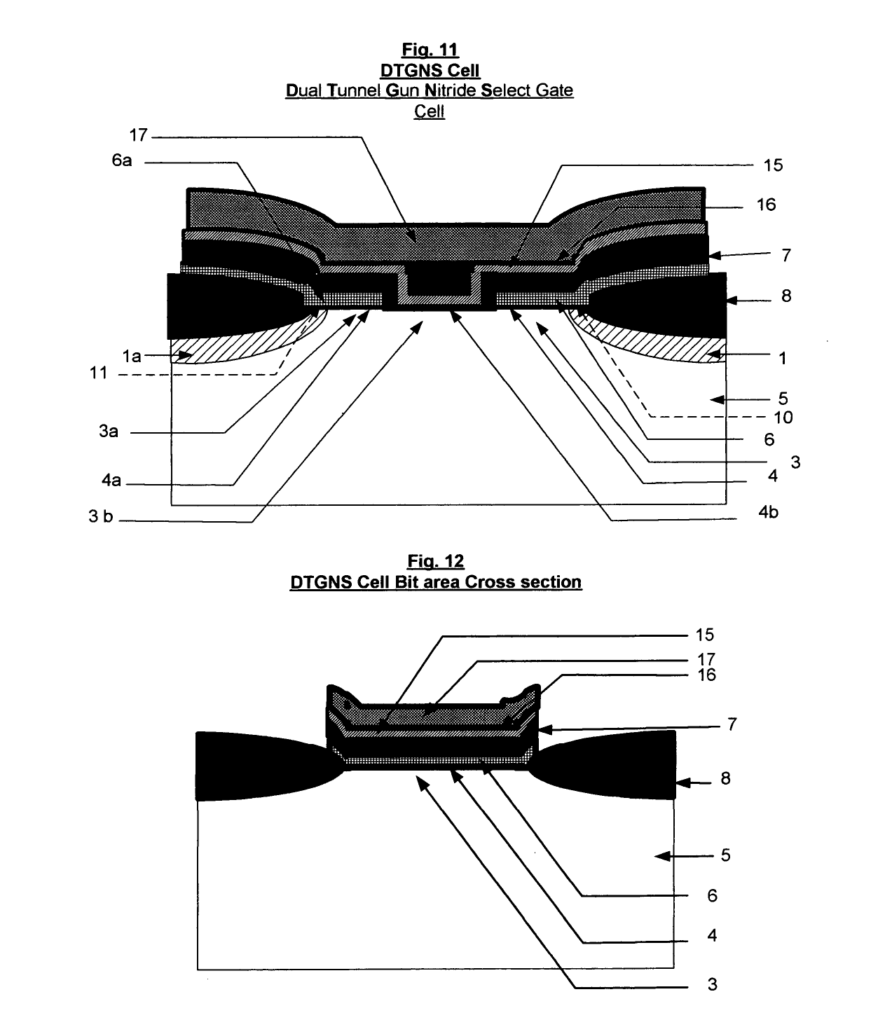

The Disclosed DNSG—FIG. 7 and FIG. 8, and TGNS—FIG. 11 and FIG. 12 Cells

1. Buried Diffusion 1 (S/D)

1a. Buried Diffusion 2 (S/D)

3 Channel under the Storage element adjacent diffusion 1

3a. Channel under Storage element adjacent diffusion 1a

3b. Select gate channel

4. Oxide layer on P-well below the Nitride layer 6 adjacent diffusion 1

4a. Oxide layer on P-well below the Nitride layer 6a adjacent diffusion 1a

4b. Gate Oxide layer on P well for select gate

5. P-Well in Silicon

6. Nitride layer adjacent the diffusion 1

6a. Nitride layer adjacent diffusion 1a

7. Oxide layer over the Nitride at 6

7a. Oxide layer over the Nitride at 6a

Note: The layers 4,6 and 7 or 4a,6a and 7a form ONO storage element layers

8. Isolation Oxide

9. Polysilicon control/Select gate layer

10. Location of Bit 1 storage

11. Location of Bit 2 storage

15. Collector grid Electrode

16. Barrier layer

17. Injector Electrode
Note: layers 15, 16 and 17 together form the Tunnel Gun (TG) structure replacing the Poly-silicon control/Select Gate layer (9)

### DESCRIPTION OF THE INVENTION

FIG. 5 shows the cross section of a NSG device with buried channel source/Drain diffusions (1) and (2) contacts and FIG. 6 is the orthogonal cross section of the same device through the Nitride gate region. The self aligned ONO sandwich with Oxide (4), Nitride layer (6), and top oxide layer (7) form the storage element with the charge being stored in traps in the Nitride (6). This structure is deposed over a silicon material (5) having a well doping of typically P type, adjacent one Source/Drain diffusion typically (10 as shown in FIG. 5. The isolation oxide regions (8) are formed using the Nitride film before the film is etched off from the region where the select gate oxide (4b) is formed. A Poly-silicon film over lying the ONO and the Gate Oxide form the integrated control gate/Select Gate conductor (9). As shown in FIG. 5 the select gate is integrated with the storage gate and the integrated channel (4 and 4b) extends from one typically n-type diffusion to the other. The select region of the channel (3b) under the Gate oxide (4b) helps to shut off the unselected channels during read operation where the control gate is grounded. During program operation the diffusion (1) forms the drain and diffusion (2) forms the source. During read this is inverted and diffusion (2 forms the drain and diffusion (1) forms the source. Hence when the control/Select Gate is turned on the select gate is turned on and the stored charge in the Nitride at the source modulate the channel current. And the stored date can be read. In the case of the unselected cells on the same diffusion line, the select gate remains shut off and do not allow current to flow in the channel. The erase is done by Band to bad tunneling with a negative voltage on select gate that keeps the device in the off condition. The issues of high voltage needed for erase with the increase in isolation distance and the drain engineering needed are not addressed by the addition of the select gate.

FIG. 7 show a Dual Nitride Select gate Cell (DNSG Cell) where the gate area is extended to have Oxide Nitride Oxide (ONO) storage regions (4,6,7 and 4a,6a,7a) adjacent to the two junctions (1 and 1a) to add two bit storage capability by adding to the cell size marginally. As discussed earlier storage area requires ONO region of 200 to 300 A only hence the increase can be limited to less than or equal to a feature size based on the process technology and masking innovations used. In the DNSG cell the select gate is formed in between the two storage ONO areas with gate oxide (4b) on silicon well, over which the control/select gate Poly-silicon (9) is defined. The Control/Select gate Poly-silicon (9) also over lay the ONO in the two storage locations allowing application of the necessary voltages during program and erase. The use of the dual storage areas increase the storage capacity of the cell area by allowing two bits to be stored and read from an area marginally larger than a single cell with one bit storage. This will increase the density of storage, almost doubling the number of bits that can be stored per unit area of silicon.

In the case the DNSG cell the programming of the bit 1 at location (10) is done by applying a suitable voltage to the diffused junction (1) making it the drain, with the diffused junction (1a) at ground, making it the source, and turning on the select gate by application of a suitable high voltage such that the channel is formed under the select gate and the voltage on the select gate is sufficient tot cause hot electrons to penetrate the ONO layer and get trapped in the trap locations in the Nitride. Similarly bit 2 can be written at location (11) by changing the voltages on the two diffused junctions, making diffusion (1a) the drain and diffusion (1) the ground or source. The erase of the junctions can be achieved by application of a high voltage to cause band to band tunneling at the junction's depletion and attracting the hot holes generated into the ONO to neutralize the stored charge in the traps in the Nitride layer. The negative voltage used to attract the holes into the ONO will keep the select gate off during erase.

Reading back the data is controlled by the select gate and the choice of diffusions for drain and source. If bit 1 data at location (10) is to be read, the diffusion close to that (1) is grounded making it a source and a read voltage is impressed on the other diffusion (1a) making it a drain. This allows the drain depletion to mask the effect of the bit 2 at location (11) while reading the modulation of the channel caused by the bit 1 at location (10), if the select gate is turned on, which is done by application of a suitable voltage on the selected control/select gate poly silicon (9). In the case of unselected cells connected to the same buried diffusion forming typical memory array, the select gate Poly-silicon is held at ground or a suitable potential to cause them to turn off and prevent the unselected cells from having any impact on the read current. Similarly bit 2 at location (11) can be read by interchanging the applied voltages to the two diffusions.

As is clear from the operation of the NSG and DNSG cells the select gate addresses the issue of leakage but does not address the issue of the high voltages and drain engineering considerations for erase of the cells by Band-to-Band tunneling. In order to address that a novel method for generation of erase carriers, typically holes, for collection by the traps in the storage electrode is proposed. This method called the Tunnel Gun or TG, uses two layers of conductors, suitably doped poly silicon or suitable metals with a thin tunnel oxide in between, to form the control gate. The bottom conductive layer is a thin layer of P-doped Poly-silicon or other metal (in this typical cell), which acts as a grid collector layer and the top layer is a thicker injector layer of P-doped Poly-silicon or suitable metal that provides carriers for ballistic tunneling across the thin barrier. Since the tunneling carriers have high energy to over come the tunnel barrier, a portion of the carriers will pass through the grid conductor if the thickness of the grid conductor is less than the mean free path of the carriers, and enter the ONO structure. If there is a voltage gradient in the ONO structure to cause the carriers to move towards the silicon traps, they will do so and get collected by the traps in the Nitride neutralizing any existing charge in the Nitride. Any residual charge will be collected by the under lying silicon.

FIG. 9 and FIG. 10 show the cross section of the Tunnel Gate Nitride cell (TGN cell) with the tunnel gun incorporated that can be used for erase. Again for simplicity an N-channel cell is described with the TG structure forming the control gate. The memory cell consists of a silicon substrate in which a P doped well (5) is formed. An ONO stack comprising a thin silicon Dioxide or SiO2 film (4) grown on the surface of silicon in the well (5), a Nitride film (6) deposited on top of the SiO2, and a second Oxide film (7) act as the storage element and is deposed between a Drain diffusion (1) and a source diffusion (2). In the current structure the drain and source diffusions are shown as being buried diffusions with oxide isolation regions (8) over them. The storage of charge happens in the traps in the Nitride film while the oxide films prevent the leakage of charge from the traps. A Tunnel Gun (TG) structure comprising a thin collector Grid electrode (15), typically a P doped Silicon layer, or high work function metal layer of thickness approximately 60-400 A, a barrier layer (16), typically a thin oxide layer of approximately 45 A and an Injector Electrode (17), typically a metal of P doped Poly layer, is deposed over the storage element and extent over the isolation. The TG structure also acts as the Control gate.

During operation the cell is programmed by application of a voltage typically of the order of 5V to the drain diffusion (1) and grounding the source diffusion (2) with a suitable high voltage being applied to the Control gate, comprising the TG structure. In this case both the Grid electrode (15) and the injection electrode (17) of the TG is shorted together to act as a control gate. The carriers in the channel get accelerated and cause impact ionization at the drain depletion. Generated carriers having the right velocity component overcome the oxide barrier of the ONO and get trapped in the Nitride layer in the traps present in the Nitride, negatively charging up the Nitride at the location. Erasing the cell is accomplished by use of the Tunnel Gun structure. A voltage difference sufficient to cause tunneling of holes across the barrier (16) by Ballistic injection is applied across the barrier from the injector (17) to the collector grid (16). These holes have high energy and velocity as they pass through the barrier. On entering the collector grid they loose velocity due to collisions and get colleted. As the mean free path of holes under these conditions is of the order of 550 A and the thickness of the collector is smaller than the mean free path length a portion of the carriers will pass through the collector and enter the oxide over the Nitride. If a field due to accumulated charge is available in the nitride or a small voltage gradient is established across the ONO stack these holes will pass into the Nitride and neutralize the charge and even charge the Nitride positive by collection in the traps in the Nitride. The use of Tunnel Gun to erase eliminate the requirement to complex drain engineering needed for handling both CHE programming and Band to Band Tunnel erase at the junctions. It also reduces the High voltages for the erase that need to be applied to the junctions. Hence allowing reduction in isolation need of the cell making the cell denser and more manufacturable.

One problem of this type of erase is that as the injection and collection happens all over the channel, the Nitride film can get charged positive and cause large unwanted leakage current in unselected cells during read.

FIG. 11 and FIG. 12 show a combination of all the innovations that have been proposed. The structure is that of a Dual Tunnel Gun Select Gate cell. Here again a Control/select gate comprising of a gate oxide (4b) and a select gate electrode comprising of the TG structure with injector layer (17), barrier (16) and collector (15), is established between two small ONO storage elements of approximately 200 to 500 A length covering the Junction and depletion regions of the buried diffusions (1 and 1a), formed of layers (4, 6,7) and (4a, 6a, and 7a) placed adjacent to diffusions (1, and 1a). The select gate allow the leakage current of the unselected cells to be eliminated from consideration during read and make he design simpler. The dual nature of the cell allows more bits to be stored per unit area of the chip increasing the density of the array. The Oxide isolation (8) is used to separate the cell from the neighbors and prevent the cells being impacted by the applied voltages on the neighboring cells.

The programming is by CHE programming. Program of bit 1 at location (10) is by application of a high voltage to the drain (1) with ground applied to the source (1a), and a high voltage to the control/select gate (TG stack) to turn on the channel and cause accumulation of charge in the nitride near the drain (1) region. Similarly by interchanging the drain and source locations the bit 2 can be programmed at location (11). Erasing the bit is by application of a voltage gradient across the TG stack of approximately 5V with a voltage gradient of approximately 1.5-3V across the ONO to cause drift of carriers into the ONO region and storage in Nitride.

The read of the cell is accomplished for bit 1 by applying a voltage to the diffusion (1a) to make it act as the drain with diffusion (1) at ground, and applying sufficient voltage turn on the channel of the select and control gates to determine the condition of the charge at (10) due to the channel modulation effect, while the effect of the charge at (11) is masked by the drain depletion region. Reversing the drain and source will enable reading the effect of the charge at location (11).

This cell by use of the two innovative techniques eliminate the very high Band to Band Tunneling voltage requirement and also the un controlled leakage current in the unselected cell. This is crucial when the cells are used in a memory array to enable correct read out of the data. The use of the dual bit allows the density of the array to be increased with minimum silicon area.

The Advantages Provided are:

1. Lower Voltages applied to the junctions allow closer packing of ells by reducing isolation needs.
2. Reduction in high voltage reduces the process complexity.
3. Replacement of Band-to-Band tunneling by TG eliminates the need for negative voltage generation on chip.
4. Elimination of Band-to-Band tunneling for erase reduces the need for high precision drain engineering.
5. The use of the smaller storage stack, storage element of smaller size, with select gate reduces the cell size growth while optimizing the storage area.
6. Addition of the select gate eliminate he problem of charge residue in the Nitride with the leakage effect in the unselected cells.
7. The select gate reduces the need for source bias to be applied to the cells during read, and hence eliminate design complexity.
8. Integrated Control/Select make the cell and design more efficient.

In fact just the addition of an integrated Control/select gate will make the Nitride Nonvolatile Memory more manufacturable, yieldable and operational by eliminating the problems of over erase and residual charge retention in the areas of Nitride spaced away from the program erase location. The use of a Dual Storage cell will make the Memory denser. In addition the use of TG to achieve erase will eliminate the critical drain engineering need for achieving CHE program and Band to Band Tunneling erase from the same junction. It also eliminates he need to generate negative voltages on the chip there by simplifying the design.

It should be noted that it is not necessary to use the TG erase in all cases. The erase can be achieved by simple FN tunneling and having the integrated select gate will eliminate the prior art problems of over erase in this case also.

As mentioned the typical cells are shown with buried diffusions for improved density. It should not be understood that the cell has to be made with buried diffusion. It is possible to have non-buried diffusions and contact them externally through contacts and metalization.

Though a number of structures with progressively more innovations have been shown it is by no means construed that all possible structures using these innovative techniques have been covered. It is evident that other structural modifications will be apparent to the users of the art as they study the disclosed techniques and structures.

What is claimed is:

1. A Non-Volatile Memory cell capable of being programmed, erased and read, having a Nitride based storage device and a select device in series between two diffusion regions forming drain and source.

2. The Non-Volatile Memory cell having an integrated Nitride based storage device and a select device in series between two diffusion regions in claim 1, where in, the Nitride Storage device comprise, an Oxide Nitride Oxide (ONO) stack forming a storage element, of sufficient size to cover the area of junction depletion region, over a storage channel region adjacent a diffusion region, and a Control/Select Gate Poly-silicon over laying the storage element.

3. The Non-Volatile Memory cell having an integrated Nitride based storage device and a select device in series between the diffusion regions in claim 1, where in, the select device comprise, a select gate oxide adjacent the storage element on one side and the second diffusion region on the other, over a select channel region, having the Control/Select gate Poly-silicon all over laying the select gate oxide.

4. The Non-Volatile Memory cell having an integrated Nitride based storage device and a select device in series between two diffusion regions in claim 1, where in, an integrated channel between the two diffusion regions is controlled by the voltage on the integrated Control/Select gate Poly-silicon and the charge stored in the storage element.

5. The Non-Volatile Memory cell having an integrated Nitride based storage device and a select device in series between two diffusions in claim 1, where in, the unwanted leakage current from un-selected cells in the array is prevented from impacting the read of the selected cell by the select gate of the unselected cells being turned off.

6. A Non-Volatile Memory cell capable of being programmed, erased and read, having two Nitride based storage devices adjacent two diffusion regions and a select device between the two storage devices, all three devices being in series over an integrated channel, across the diffusion regions forming drain and source.

7. The Non-Volatile Memory cell capable of being programmed, erased and read, having two Nitride based storage devices adjacent two diffusion regions and a select device between the two storage devices, all three devices being in series over an integrated channel, across the diffusion regions forming drain and source in claim 6, where in, the cell is capable of storing two bits, one in each storage element.

8. The Non-Volatile Memory cell capable of being programmed, erased and read, having two Nitride based storage devices adjacent two diffusion regions and a select device between the two storage devices, all three devices being in series over an integrated channel, across the diffusion regions forming drain and source in claim 6, where in, the impedance of the integrated channel is controlled by the voltage applied to a control/select Poly-silicon and the stored charge on the storage device adjacent the source diffusion while the effect of the stored charge on the storage device adjacent the drain is masked by the drain depletion region.

9. The Non-Volatile Memory cell capable of being programmed, erased and read, having two Nitride based storage devices adjacent two diffusion regions and a select device between the two storage devices, all three devices being in series over an integrated channel, across the diffusion regions forming drain and source in claim 6, where in, the unwanted leakage current from un-selected cells in the array is prevented from impacting the read of the selected bit, by the select gate of the unselected cells being turned off.

10. A Non Volatile Memory cell that is capable of being programmed, erased and read back having at least one Nitride based storage element adjacent a diffusion, over a channel region in silicon between two diffusion regions, where the erase is by use of a Tunnel Gun structure comprising a conductive Collector Grid layer over and adjacent to the storage element, a conductive Injector layer over laying the Collector Grid layer, but separated from it by a barrier layer.

11. The Non Volatile Memory cell that is capable of being programmed, erased and read back having a Nitride based storage element over a channel region in silicon between two diffusion regions where the erase is by use of a Tunnel Gun structure, in claim 10, where in, Grid Collection layer has a thickness smaller than the mean free path length of the carrier used for erase in the layer material.

12. The Non Volatile Memory cell that is capable of being programmed, erased and read back having a Nitride based storage element over a channel region in silicon between two diffusion regions where the erase is by use of a Tunnel Gun structure, in claim 10, where in, the Tunnel Gun comprise of a conductive Collector Grid layer over and adjacent to the storage element, a conductive Injector layer over laying the Collector Grid layer but separated from it by a barrier layer.

13. The Non Volatile Memory cell that is capable of being programmed, erased and read back having a Nitride based storage element over a channel region in silicon between two diffusion regions where the erase is by use of a Tunnel Gun structure, in claim 10, where in, the use of the Tunnel Gun structure enable reduction junction potential by elimination of high Band to Band Tunneling voltage during cell erase operation.

14. The Non Volatile Memory cell that is capable of being programmed, erased and read back having a Nitride based storage element over a channel region in silicon between two diffusion regions where the erase is by use of a Tunnel Gun structure, in claim 10, where in, the use of Tunnel Gun for erase eliminate the Band to Band tunneling erase and the associated complexity of drain engineering to make the cell more manufacturable.

15. The Non Volatile Memory cell that is capable of being programmed, erased and read back having a Nitride based storage element over a channel region in silicon between two diffusion regions where the erase is by use of a Tunnel Gun structure, in claim 10, where in, the Collector grid and the Injector are metal layers.

16. The Non Volatile Memory cell that is capable of being programmed, erased and read back having a Nitride based storage element over a channel region in silicon between two diffusion regions where the erase is by use of a Tunnel Gun structure, in claim 10, where in, the Collector Grid and the Injector are poly-silicon layers.

17. The Non Volatile Memory cell that is capable of being programmed, erased and read back having a Nitride based storage element over a channel region in silicon between two diffusion regions where the erase is by use of a Tunnel Gun structure, in claim 10, where in, the Collector grid is a metal layer and Injector is a poly-silicon layer

18. The Non Volatile Memory cell that is capable of being programmed, erased and read back having a Nitride based storage element over a channel region in silicon between two diffusion regions where the erase is by use of a Tunnel Gun structure, in claim 10, where in, the Collector grid is a Poly-silicon layer and Injector is a metal layer

19. The Non Volatile Memory cell that is capable of being programmed, erased and read back having a Nitride based storage element over a channel region in silicon between two diffusion regions where the erase is by use of a Tunnel Gun structure, in claim 10, where in, the barrier is an insulating oxide layer.

20. A Non-Volatile Memory cell having the ability to store two bits of data simultaneously and having the capability to be programmed, erased and read, having two Nitride based storage devices adjacent two diffusion regions and a select device between the two storage devices, all three devices being in series over an integrated channel, across the diffusion regions forming drain and source where the erase is by use of a Tunnel Gun structure comprising a conductive Collector Grid layer over and adjacent to the storage element, a conductive Injector layer over laying the Collector Grid layer, but separated from it by a barrier layer.

21. The Non Volatile Memory cell having the ability to store two bits of data simultaneously and having the capability to be programmed, erased and read, having two Nitride based storage devices adjacent two diffusion regions and a select device between the two storage devices, all three devices being in series over an integrated channel, across the diffusion regions forming drain and source where the erase is by use of a Tunnel Gun structure in claim 20, where in, the unwanted leakage current from un-selected cells in the array is prevented from impacting the read of the selected bit, by the select gate of the unselected cells being turned off.

22. The Non Volatile Memory cell having the ability to store two bits of data simultaneously and having the capability to be programmed, erased and read, having two Nitride based storage devices adjacent two diffusion regions and a select device between the two storage devices, all three devices being in series over an integrated channel, across the diffusion regions forming drain and source where the erase is by use of a Tunnel Gun structure in claim 20, where in, the use of the Tunnel Gun structure enable reduction junction potential by elimination of the high Band to Band Tunneling voltage in cell erase operation.

23. The Non Volatile Memory cell capable of being programmed, erased and read, having two Nitride based storage devices adjacent two diffusion regions and a select device between the two storage devices, all three devices being in series over an integrated channel, across the diffusion regions forming drain and source where the erase is by use of a Tunnel Gun structure in claim 20, where in, the elimination of Band to Band tunneling erase reduce the need for complex drain engineering for the cell, for improve manufacturability.
